(19) United States
(12) Patent Application Publication
(10) Pub. No.: US 2015/0155464 A1
(43) Pub. Date: Jun. 4, 2015

(54) Thermoelectric Structures and Devices Based on Topological Insulators

(71) Applicant: ENN Science and Technology Development Co., Ltd, Langfang (CN)

(72) Inventors: Yong Xu, Palo Alto, CA (US); Zhongxue Gan, Langfang (CN); Shou-Cheng Zhang, Stanford, CA (US)

(21) Appl. No.: 14/207,478

(22) Filed: Mar. 12, 2014

Related U.S. Application Data
(60) Provisional application No. 61/910,541, filed on Dec. 2, 2013.

(51) Int. Cl. H01L 35/32; H01L 35/34

(52) U.S. Cl. CPC H01L 35/32; H01L 35/34

(57) ABSTRACT

Method and apparatus are provided for improving the thermoelectric figure of merit (zT) for thermoelectric structures and devices based on topological insulators. In one novel aspect, the zT of the TI is increased by optimizing geometric sizes of the TI. In one embodiment, the zT is increased by increasing the length of the TI to be greater than the inelastic mean free path length. In another embodiment, the zT is increased by decrease the width of a 2D TI to be about three times the localized localization width ξ of the boundary state of the TI, or to decrease the thickness of a 3D TI to be about three times of ξ. In one novel aspect of the current invention, methods are provided to increase zT of the TI by substantially maximizing a relative thermoelectric-transport contribution of the boundary state with respect to the bulk states.

### CROSS REFERENCE TO RELATED APPLICATIONS

This application claims priority under 35 U.S.C. §119 from U.S. Provisional Application No. 61/910,541, entitled “Thermoelectric Structures and Devices based on Topological Insulators” filed on Dec. 2, 2013; the subject matter of which is incorporated herein by reference.

### TECHNICAL FIELD

The disclosed embodiments relate generally to thermoelectric structures and devices, and, more particularly, to thermoelectric structures and devices based on topological insulators.

### BACKGROUND

The worldwide demand for energy supply continues to grow rapidly. At the same time, there are increasing concerns of environmental problems from emissions using traditional fossil energy materials such as gas, oil and coal. In recent years, extensive research has been done to search for alternative green energy materials. Thermoelectric effects have long been known to enable direct conversion between thermal and electrical energy and provide a viable alternative route for power generation and refrigeration. The search of high-performance thermoelectric (TE) materials for efficient heat-electricity inter-conversion is a long-sought goal of material science. [Electronic refrigeration, vol. 76 (Pion London, 1986); Adv. Mater. 19, 1043 (2007); Nat. Mater. 7, 105 (2008)].

The thermo-electric conversion efficiency depends on the thermoelectric figure of merit zT of thermoelectric materials. zT, however, is a combination of conflicting properties. In a typical definition, zT is written as:

$$zT = \frac{σ {S}^{2} T}{κ} ,$$

where σ is the electrical conductivity, S is the Seebeck coefficient, T is the absolute temperature and the thermal conductivity κ is the sum of contributions from electrons κₑ and lattice vibrations κₗ. To achieve high zT, one requires a high electrical conductivity σ, a large Seebeck coefficient S, and a low thermal conductivity κ. In general, increasing the charge carrier concentration enhances the electrical conductivity σ but decreases the Seebeck coefficient S. In addition, an increase in the electrical conductivity σ leads to an increase in the thermal conductivity of κ. Therefore, a modification to any one of the parameters could adversely affect other transport coefficients such that the resulting zT does not improve significantly. [Electronic refrigeration, vol. 76 (Pion London, 1986)]. Improving the thermoelectric figure of merit zT is one of the greatest challenges in material science.

Recent discovery of new quantum states of matter, topological insulators (TIs) [Rev. Mod. Phys. 82, 3045 (2010); Rev. Mod. Phys. 83, 1057 (2011)], sheds new light on pursuing TI materials of high zT. How to optimize the TI structures such the zT can be dramatically increased continues to be a big challenge.

### SUMMARY

Method and apparatus are provided for improving the thermoelectric figure of merit (zT) for thermoelectric structures and devices based on topological insulators. In one novel aspect of the current invention, a topological insulator (TI) with a cross sectional area A and an electrical and thermal transport path along a longitudinal direction with a length L is provided. The TI has a bulk state with an insulating gap and a boundary state that is gapless and protected from any time reversal invariant perturbation. In one embodiment of the current invention, the zT of the TI is increased by increasing L and decreasing A. In another embodiment of the current invention, the TI structure has a L that is great than the inelastic mean free path λ of TI. In one embodiment of the current invention, the TI is a two-dimensional (2D) TI having an edge state, and the zT is increased by minimizing the width of the 2D TI to about three times of the localization width ξ of the TI. In another embodiment of the current invention, the TI is a three-dimensional (3D) TI having a surface state, and the zT is increased by minimize the thickness of the 3D TI to about three times of the localization width ξ of the TI.

In another novel aspect of the current invention, the Fermi level of the TI is tuned to increase the zT of the TI. In one embodiment of the current invention, chemical dopants are added to the TI such that the TI has a Fermi level of about zero to three k_{B}T below the bulk valence band maximum (VBM) for a P-Type TI or about zero to three k_{B}T above the bulk conduction band minimum (CBM) for an N-Type TI. In another embodiment of the current invention, the TI is formed from material (BiₓSb₁₋ₓ)₂Te₃. The composition is tuned by setting x to be greater than zero and smaller than one such that the TI has a Fermi level of about zero to three k_{B}T below the bulk valence band maximum (VBM) for a P-Type TI or about zero to three k_{B}T above the bulk conduction band minimum (CBM) for an N-Type TI. In one embodiment of the current invention, x is about 0 to 0.1 for a P-type TI, or x is about 0.9 to 1 for an N-type TI.

In another novel aspect of the current invention, disorders are added to the bulk region of the TI to increase zT of the TI. In one embodiment of the current invention, the disorders in the bulk region are away from the boundary region of the TI such that the disorders scatter phonons and bulk state electrons while keeping the boundary state little affected.

In one novel aspect of the current invention, methods are provided to increase zT of the TI by substantially maximizing a relative thermoelectric-transport contribution of the boundary state with respect to the bulk states. In one embodiment of the current invention, the methods includes: obtaining an inelastic mean free path λ of the TI and obtaining a localization width ξ of the boundary state of the TI, and increasing the zT based on λ and ξ. In one embodiment of the current invention, the method includes to increase the length of the TI to be greater than the inelastic mean free path λ of the TI. In another embodiment of the current invention, the method includes to decrease the width of a 2D TI to be about three times of the localization width ξ of the boundary state of the TI. In another embodiment of the current invention, the method involves to decrease the thickness of a 3D TI to be about three times of the localization width ξ of the boundary state of the TI.

In another novel aspect of the current invention, methods are provided to increase the zT of the TI by tuning the Fermi level of the TI. In one embodiment of the current invention, the Fermi level of the TI is tuned through electrical gating. In another embodiment of the current invention, the Fermi level of the TI is tuned through chemical doping. In another embodiment of the current invention, the Fermi level of the TI is tuned through composition tuning.

### BRIEF DESCRIPTION OF THE DRAWINGS

FIG. 1 shows a thermoelectric couple using TI for Seebeck-effect power generation.

FIG. 2 shows a thermoelectric couple using TI for Peltier-effect cooling.

FIG. 3 shows a thermoelectric module using multiple thermoelectric couples composed of N-type and P-Type TIs for Seebeck-effect power generation.

FIG. 4 shows a thermoelectric module using multiple thermoelectric couples composed of N-type and P-Type TIs for Peltier-effect cooling.

FIG. 5 is a schematic diagram of the energy-band structure and spin orientation for topological insulators.

FIG. 6 is a schematic diagram depicting helical edge states of two-dimensional (2D) TIs.

FIG. 7 is a schematic diagram of a 2D TI for thermoelectric devices in accordance with some embodiments of the current invention.

FIG. 8 a schematic diagram of a three-dimensional (3D) TI for thermoelectric devices in accordance with some embodiments of the current invention.

FIG. 9 illustrates geometric size dependence of zT in a TI material.

FIG. 10 illustrates an optimization of Fermi level for N-type TI.

FIG. 11 illustrates an optimization of Fermi level for P-type TI.

FIG. 12A shows a 2D TI with disorders in the bulk region such that the zT of the TI is increased.

FIG. 12B shows a 3D TI with disorders in the bulk region such that the zT of the TI is increased.

FIG. 13 is a diagram of the optimized zT as a function of length and width for a 2D TI fluorinated stanene at 300K.

FIG. 14 is a flow diagram of methods to increase zT according to embodiments of the current invention.

### DETAILED DESCRIPTION

Reference will now be made in detail to some embodiments of the invention, examples of which are illustrated in the accompanying drawings.

Using TE materials for power generator or solid-state pump cooler has promising competitive advantages over the conventional energy conversion systems. The key to the success of using TE materials is to further improve their zT. Any small increment in zT will result in many new applications. Recent discovery of topological insulators (TIs) sheds new light on high-efficient TE materials.

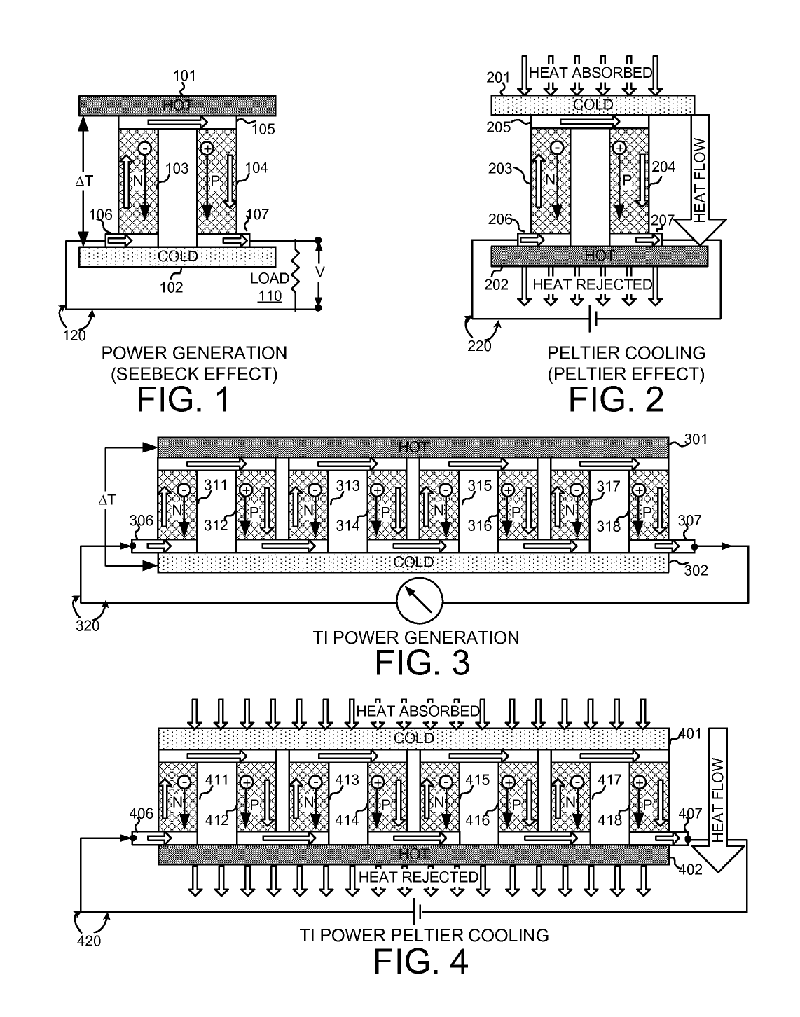

FIG. 1 shows a thermoelectric couple using TI for Seebeck-effect power generation. A Seebeck-effect power thermoelectric generator uses heat flow across a temperature gradient to generate electricity power. A hot plate 101 and a cold plate 102 have a temperature difference of ΔT. An N-type TI structure 103, which contains free electrons as charge carriers, is coupled between metal contacts 105 and 106. A P-type TI structure 104, which contains free holes as charge carriers, is coupled between metal contacts 105 and 107. The temperature difference between plates 101 and 102 provides a load voltage 110 for a circuit 120 from the Seebeck effect while the heat flow drives the electrical current. To improve the efficiency of the power generation from the Seebeck effect, TI materials are used for 103 and 104. In one embodiment of the current invention, the efficiency is further improved by maximizing a relative thermoelectric-transport contribution of the boundary state with respect to the bulk states of the TI material.

FIG. 2 shows a thermoelectric couple using TI for Peltier-effect cooling. A Peltier-effect cooler is a solid-state heat pump that utilizes the Peltier effect to pump heat. A circuit 220 has an external power supply. Circuit 220 is connected to metal contacts 206 and 207. An N-type TI structure 203, which contains free electrons as charge carriers, is coupled between metal contacts 205 and 206. A P-type TI structure 204, which contains free holes as charge carriers, is coupled between metal contacts 205 and 207. A cold plate 201 is attached to metal contact 205 and a hot plate 202 is attached to metal contacts 206 and 207. Cold plate 201 absorbs heat while hot plate 202 rejects heat. Heat flows from plate 201 to plate 202. Therefore, the heat gets pumped when circuit 220 provides power. The efficiency of the Peltier-effect cooler depends on the zT of the TE material. In one embodiment of the current invention, as shown, TI materials are used for 203 and 204 to improve efficiency. In another embodiment of the current invention, the efficiency is further improved by maximizing a relative thermoelectric-transport contribution of the boundary state with respect to the bulk states of the TI material.

FIG. 3 shows a thermoelectric module using multiple thermoelectric couples composed of N-type and P-Type TIs for Seebeck-effect power generation. A thermoelectric module for Seebeck-effect power generation contains many thermoelectric couples, as shown in FIG. 1, which has N-type and P-type thermoelectric structures wired electrically in series, and thermally in parallel. A hot plate 301 and a cold plate 302 have a temperature difference of ΔT. An N-type TI structure 311 is coupled between metal contacts and connected with a P-type TI structure 312 forming a first thermoelectric couple. Similarly, an N-type TI structure 313 and a P-type TI structure 314 forms a second thermoelectric couple. An N-type TI structure 315 and a P-type TI structure 316 forms a third thermoelectric couple. An N-type TI structure 317 and a p-type TI structure 318 forms a fourth thermoelectric couple. The first, second, third and fourth thermoelectric couples are wired electrically in series and thermally in parallel. The first thermoelectric couple is connected to a metal contact 306. The fourth thermoelectric couple is connected to a metal contact 307. A circuit 320 is connected with metal contacts 306 and 307. The temperature difference between plates 301 and 302 provides a load voltage from the Seebeck effect while the heat flow drives the electrical current to circuit 320 through the thermoelectric module. In one embodiment of the current invention, the efficiency of the Seebeck-effect power generation system is improved by increasing the zT of the TI structures. In one novel aspect of the current invention, the method of increasing the ZT involves optimizing the geometric sizes of the TI structures.

FIG. 4 shows a thermoelectric module using multiple thermoelectric couples composed of N-type and P-Type TIs for Peltier-effect cooling. A thermoelectric module for Peltier-effect cooling contains many thermoelectric couples, as shown in FIG. 2, which has N-type and P-type thermoelectric structures wired electrically in series, and thermally in parallel. A cold plate 401 and a hot plate 402 have a temperature difference of ΔT. An N-type TI structure 411 is coupled between metal contacts and connected with a P-type TI structure 412 forming a first thermoelectric couple. Similarly, an N-type TI structure 413 and a P-type TI structure 414 forms a second thermoelectric couple. An N-type TI structure 415 and a P-type TI structure 416 forms a third thermoelectric couple. An N-type TI structure 417 and a p-type TI structure 418 forms a fourth thermoelectric couple. The first, second, third and fourth thermoelectric couples are wired electrically in series and thermally in parallel. The first thermoelectric couple is connected to a metal contact 406. The fourth thermoelectric couple is connected to a metal contact 407. A circuit 420 has an external power supply that is connected with metal contacts 406 and 407. Heat flows from plate 401 to plate 402. Therefore, the heat gets pumped when circuit 420 provides power. In one embodiment of the current invention, the efficiency of the Peltier-effect cooling system is improved by increasing the zT of the TI structures. In one novel aspect of the current invention, the method of increasing the zT involves optimizing the geometric sizes of the TI structures. The efficiency of the Peltier-effect cooling system depends on the zT of the TE material. In one embodiment of the current invention, the efficiency of the Peltier-effect cooling system is improved by increasing the zT of the TI structures. In one novel aspect of the current invention, the method of increasing the ZT involves optimizing the geometric sizes of the TI structures.

As shown above, using TI as building blocks for thermoelectric power generator or cooler offers promising commercial applications compared to traditional thermoelectric materials. TIs are new quantum states of matter characterized by an insulating bulk gap and gapless edge or surface, which are protected by the time-reversal symmetry. TIs share similar material properties, namely heavy elements and narrow band gaps, with TE materials. Consequently, many currently known TIs, such as Bi₂Te₃, Sb₂Te₃ and BiₓSb₁₋ₓ are also excellent TE materials. However, traditionally, the novel aspects of the edge/surface states of TIs attribute to TE effects are not known. The nontrivial TI edge and surface states are advantageous in improving the thermoelectric figure of merit zT. Distinct from conventional materials, TIs support topologically protected boundary (surface or edge) states together with bulk states, and the two types of charge carriers exhibit distinct transport properties in different dimensions.

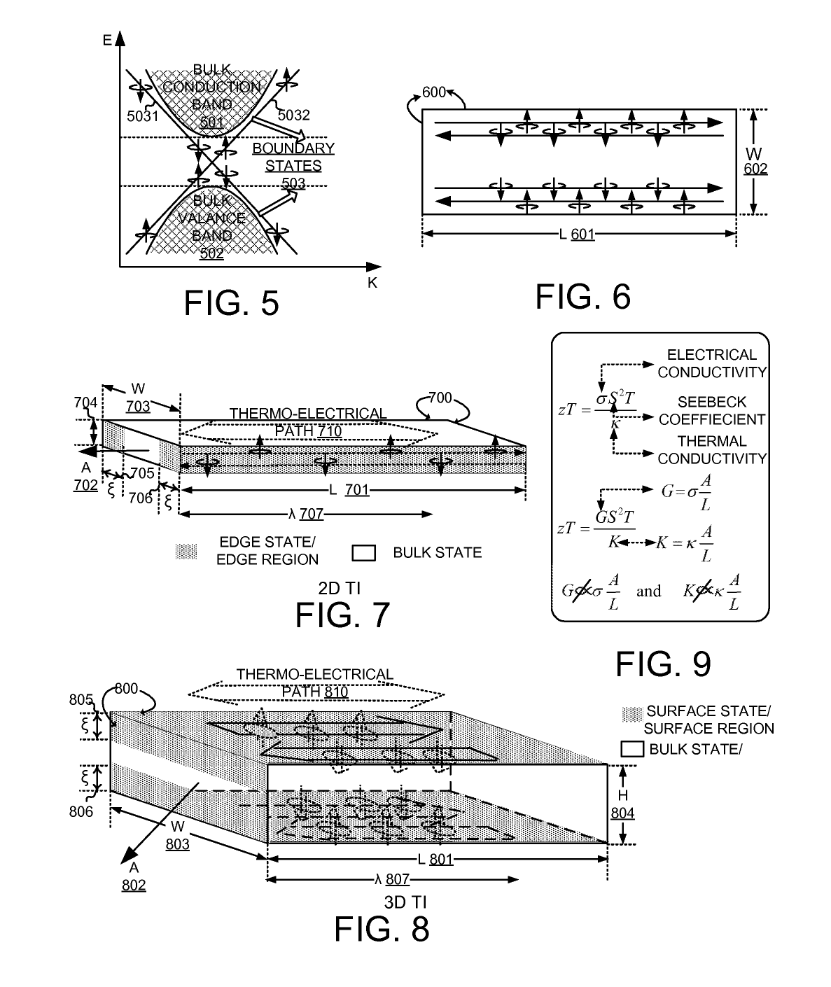

FIG. 5 is a schematic diagram of the energy-band structure and spin orientation for topological insulators. A topologic insulator has a bulk conduction band 501 and a bulk valance band 502. Boundary states 503 are gapless with bands dispersing inside the bulk gap and helical with spin-momentum locking. Without losing generality, boundary state 5031 has up spin and boundary state 5032 has down spin. Another special characteristic of the TI is that when the Fermi level E_{F} is within the bulk gap, boundary states 503 are protected by the time reversal symmetry against backscattering.

FIG. 6 is a schematic diagram depicting helical edge states of two-dimensional (2D) TIs. A 2D TI 600 has a length of L 601 and a width of W 602. The gapless boundary state exists at the edge of TI 600 along the longitudinal direction of L 601. The unique characteristics of edge state of the 2D TI makes it possible to increase zT by optimize the length and/or width of TI 600, such that the relative thermoelectric-transport contribution of the boundary state with respect to the bulk states is maximized. The inelastic mean free path λ is an index of how far an electron can travel through a solid state before losing energy. As a unique feature of TI materials, electrons in gapless boundary states are protected against backscattering by time-reversal symmetry, thus have λ much greater than electrons in the bulk states. In one embodiment of the current invention, L 601 is increased to greater than λ of edge state for TI 600. This optimization increases the thermoelectric-transport contribution from the edge state because the electrons of bulk states experience more scattering than electrons of edge states due to this optimization process. Further, the width W 602 of TI 600 also can be optimized to increase zT of TI 600. Because the contribution to the thermoelectric-transport is proportional to the area of the bulk state/edge state, decreasing W 602 would increase the relative contribution from the edge state. However, W 602 needs to be large enough to avoid hybridization between edge states from opposite edges. The distribution of wavefunction of the boundary state in space is characterized by a localization width ξ. In one embodiment of the current invention, W 602 is optimized to be around two times of a localization width ξ of the boundary state of the TI. In another embodiment of the current invention, W 602 is optimized to be around three times of a localization width ξ of the boundary state of the TI. It is noted that though FIG. 6 gives an exemplary diagram for a 2D TI, the same principles applies to 3D TIs.

FIG. 7 is a schematic diagram of a 2D TI for thermoelectric devices in accordance with some embodiments of the current invention. A 2D TI 700 has a length L 701 and a cross sectional area A 702. Cross sectional area A 702 has a width W 703 and a thickness H 704. 2D TI 700 has edge state at the edges of TI 700 along the longitudinal direction L 701. A charge-carrier-transport direction is along the longitudinal direction. A thermal transport path 710 is also the longitudinal direction. 2D TI 700 has an inelastic mean free path λ 707 of the boundary state along the longitudinal direction. Mean free path λ 707 is measurable. A localization width ξ 705 and a localization width ξ 706 are measurable from the edges of TI 700. Localization width ξ 705 and localization width ξ 706 vary from different materials. For example, HgTe/CdTe has a localization width ξ about 50 nm [Phys. Rev. Lett. 101, 246807 (2008)]; Bi thin film has a localization width about 6 nm [Phys. Rev. B 83, 121310(R) (2011)]; and Sn thin films has a localization width ξ about 4 nm.

2D TI 700 can be thin film materials, such as Si, Ge, Sn, Sb, Bi, Bi2TeI, ZrTe5 and HfTe5. 2D TI 700 can also be heterostructures such as HgTe/CdTe, InAs/GaSb. H 704 of 2D TI is very small, on the order of nanometers. The zT of TI 700 can be increased by optimize L 701 and A 702 such that the relative thermoelectric-transport contribution of the boundary state with respect to the bulk states is maximized. In particular, L 701 is increased and/or A 702 is decreased to increase the zT of TI 700. In one embodiment of the current invention, L 701 is increased to greater than λ of the boundary state for TI 700. In another embodiment of the current invention, W 703 is decreased to about three times of a localization width ξ of the boundary state of the TI. In one embodiment of the current invention, the width of TI 700 is set to about 10 to 100 nm. In another preferred embodiment of the current invention, the width of TI 700 is set to about 10 to 20 nm.

FIG. 8 shows a schematic diagram of a three-dimensional (3D) TI for thermoelectric devices in accordance with some embodiments of the current invention. A 3D TI 800 has a length L 801 and a cross sectional area A 802. Cross sectional area A 802 has a width W 803 and a thickness H 804. 3D TI 800 has surface states at the top and bottom surfaces of TI 800 along the longitudinal direction L 801. A charge-carrier-transport direction is along the longitudinal direction. A thermal transport path 810 is also the longitudinal direction. Mean free path λ 807 is measurable. A localization width ξ 805 and a localization width ξ 806 are measurable from the surfaces of TI 800. Localization width ξ 805 and localization width 806 vary from different materials.

3D TI 800 materials include BiₓSb₁₋ₓ, Bi₂Se₃, Bi₂Te₃, Sb₂Te₃, Bi₂Te₂Se, Bi₂Te₂S, Tl(Bi,Sb)(Te,Se,S)₂, ternary Heusler compounds, filled skutterudites, and chalcogenides, like GeBi₄Te₇, Ge₂Bi₂Te₅, and GeBi₂Te₄, PbBi₂Se₄, PbSb₂Te₄. The zT of TI 800 can be increased by optimize L 801 and A 802 such that the relative thermoelectric-transport contribution of the boundary state with respect to the bulk states is maximized. In particular, L 701 is increased and/or A 802 is decreased to increase the zT of TI 800. In one embodiment of the current invention, L 801 is increased to greater than λ of the boundary state for TI 800. In another embodiment of the current invention, H 804 is decreased to about three times of a localization width ξ of the boundary state of the TI. In one embodiment of the current invention, the thickness of TI 800 is set to about 5 nm to 100 nm. In another preferred embodiment of the current invention, the width of TI 800 is set to about 5 nm to 50 nm.

FIG. 9 illustrates geometric size dependence of zT in a TI material. As shown in FIG. 9, the thermoelectric figure of merit zT is traditionally expressed as:

$$zT = \frac{σ {S}^{2} T}{κ} \qquad ( 1 )$$

where σ is the electrical conductivity, S is the Seebeck coefficient, T is the absolute temperature and the thermal conductivity κ is the sum of contributions from electrons κₑ and lattice vibrations κₗ. The use of this definition inexplicitly assumes that zT is an intrinsic material property independent of the geometric size. However, this basic assumption does not always hold, as it is the case for TIs. The following is a general definition of zT that can describe the general geometric size dependence. Using simple derivations based on thermodynamics [Introduction to thermoelectricity, vol. 121 (2009)], zT is described as:

$$zT = \frac{G {S}^{2} T}{K} \qquad ( 2 )$$

Where G is the electrical conductance and K=Kₑ+Kₗ is the thermal conductance. According to Ohm's scaling law in the diffusive transport regime, G=σA/L and Fourier's scaling law in the diffusive transport regime K=κA/L, where A is the cross section area and L is the length of a material. The geometry factor A/L cancels between G and K. Then if S is size independent, so would be zT. Therefore, when S is size independent, Equations (1) and (2) are equivalent.

However, generally zT can be size dependent caused by two mechanisms: (i) Ohm's scaling law and/or Fourier's scaling law fail; (ii) S depends on the geometric size. Finding the right material that possesses the above mechanisms is a key to further increase zT by optimizing geometric size of the material. TI materials used for thermoelectric devices take advantage of such mechanisms. First, for TI materials, Ohm's scaling law does not apply because boundary and bulk states distribute in different physical dimensions. Therefore, G is no longer proportional to A/L. In addition, as boundary states have mean free paths significantly longer than bulk states, it is possible to see unusual length-dependent transport behaviors, such as ballistic transport of the boundary states and diffusive transport of the bulk states. Second, the Seebeck effect in a TI material are contributed by both bulk and boundary states. Since transport of the two types of charge carriers have distinct geometric size dependence, the total Seebeck coefficient S is strongly geometric size dependent.

Due to the unique characteristic of boundary states of TIs, it is possible to increase zT by optimizing geometric sizes of TI materials. It is desirable to increase the relative thermoelectric-transport contribution of the boundary state with respect to the bulk state. In one embodiment of the current invention, the optimization is achieved by increasing the length of a TI structure to greater than the mean free path length of the boundary state. In another embodiment of the current invention, the optimization is achieved by decreasing the cross sectional area. For a 2D TI material, decreasing the cross sectional area involves decreasing the width of the 2D TI to about three times of a localization width ξ of the boundary state of the TI. For a 3D TI material, decreasing the cross sectional area involves decreasing the thickness of the 3D TI to about three times of a localization width ξ of the boundary state of the TI.

Adjusting geometric size of a TI structure can increase zT of the material. Other ways to increase zT are to adjust the Fermi level of the material and to add disorders to the TI.

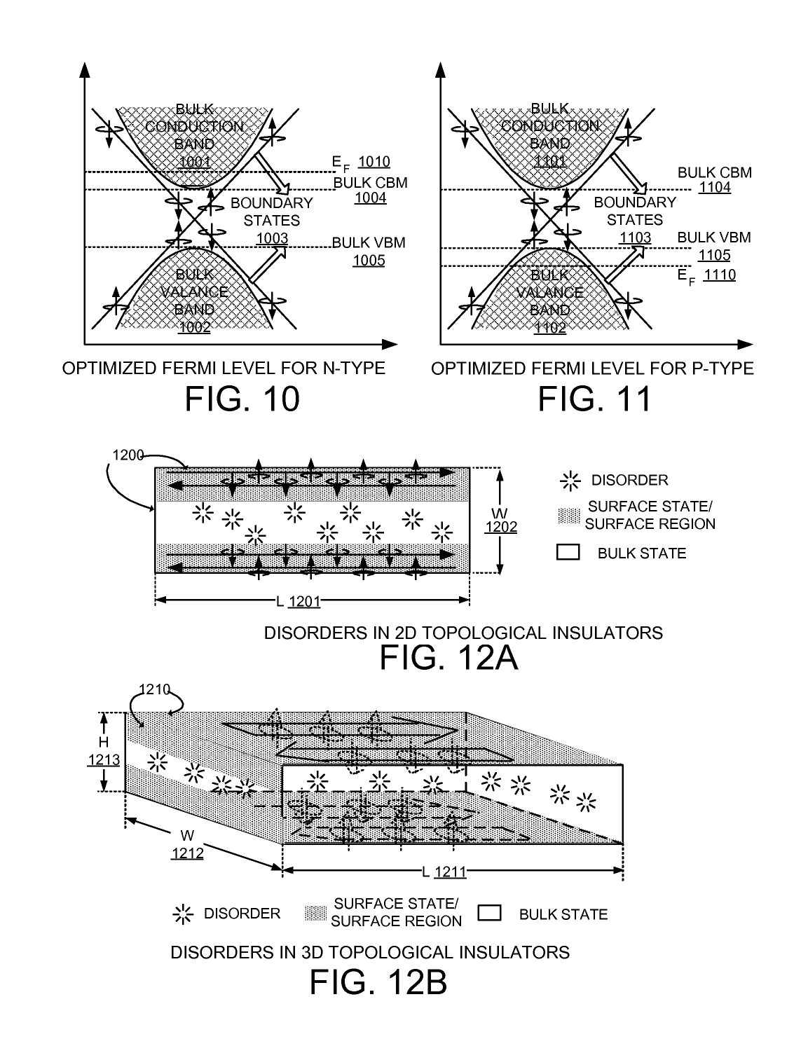

FIG. 10 illustrates an optimization of Fermi level for N-type TI. A topologic insulator has a bulk conduction band 1001 and a bulk valance band 1002. Boundary states 1003 are gapless with bands dispersing inside the bulk gap and helical with spin-momentum locking. Without losing generality, bulk conduction band 1001 and bulk valance band 1002 are shown to have parabolic dispersion. Bulk conduction band minimum (CBM) 1004 represent the bottom of the bulk conduction band. Bulk valance band maximum (VBM) 1003 represents the top of the bulk valance band. Boundary states 1003 have linear energy dispersion. For an N-type TI, the zT is optimized by tuning Fermi level E_{F}. E_{F} 1010 is in unit of k_{B}T, where k_{B} is Boltzmann constant and T is an average temperature of the TI. In one embodiment of the current invention, as shown in FIG. 10, E_{F} 1010 is about zero to three k_{B}T above bulk CBM 1004 for an N-type TI.

FIG. 11 illustrates an optimization of Fermi level for P-type TI. A topologic insulator has a bulk conduction band 1101 and a bulk valance band 1102. Boundary states 1103 are gapless with bands dispersing inside the bulk gap and helical with spin-momentum locking. Without losing generality, bulk conduction band 1101 and bulk valance band 1102 represents are shown to have parabolic dispersion. Bulk conduction band minimum (CBM) 1104 represents the bottom of the bulk conduction band. Bulk valance band maximum (VBM) 1103 represents the top of the bulk valance band. Boundary states 1103 have linear energy dispersion. For a P-type TI, the zT is optimized by tuning Fermi level E_{F}. E_{F} 1110 is in unit of k_{B}T, where k_{B} is Boltzman constant and T is an average temperature of the TI. In one embodiment of the current invention, as shown in FIG. 11, E_{F} 1110 is about zero to three k_{B}T below bulk VBM 1104 for a P-type TI.

As shown in FIG. 10 and FIG. 11, tuning Fermi level E_{F} can increase zT for P-type or N-type TI materials. There are a few ways to tune the Fermi level E_{F}. In one embodiment of the current invention, electrical gating is used to tune E_{F} to be about zero to three k_{B}T above bulk CBM 1004 for an N-type TI or to be about zero to three k_{B}T below bulk VBM 1104 for a P-type TI. In another embodiment of the current invention, adding chemical dopants is used to tune Fermi level E_{F}. Different dopants are added to the TI materials such that E_{F} is about zero to three k_{B}T above bulk CBM 1004 for an N-type TI or about zero to three k_{B}T below bulk VBM 1104 for a P-type TI.

In one embodiment of the current invention, Fermi level E_{F} can be tuned using composition tuning methods. In a preferred embodiment of the current invention, a composition (BiₓSb₁₋ₓ)₂Te₃ is used as TI material. The composition is tuned such that E_{F} is about zero to three k_{B}T above bulk CBM 1004 for an N-type TI or about zero to three k_{B}T below bulk VBM 1104 for a P-type TI. In the composition, x is greater or equal than zero and less or equal than one. In one preferred embodiment of the current invention, x is tuned to be about 0 to 0.1 for a P-type TI, and x is tuned to be about 0.9 to 1 for an N-type TI.

Another way to increase zT for TIs is to introduce defects or disorders away from a boundary region of the TI such that the disorders scatter phonons and bulk state electrons while keeping the boundary state little affected.

FIG. 12A shows a 2D TI 1200 has a length L 1201, a width 1202 and a thickness 1203. 2D TI 1200 has edge states at the edges of TI 1200 along the longitudinal direction L 1201. A charge-carrier-transport direction is along the longitudinal direction. Disorders are added away from the edge region of TI 1200. Therefore, the disorders scatter phonons and electrons in the bulk state. As result, the contribution to the thermoelectric-transport from the bulk state is decreased. Because the disorders are away from the edge region, it has little effect to the contribution to thermoelectric-transport from the edge state. The zT of TI 1200 is thereby increased. The zT of the 2D TI is increased.

FIG. 12B shows a 3D TI with disorders away from the boundary region such that the zT of the TI is increased. A 3D TI 1210 has a length L 1211, a width 1212 and a thickness 1213. 3D TI 1210 has surface states at the top and bottom surfaces of TI 1210 along the longitude L 1211. A charge-carrier-transport direction is along the longitudinal direction. Disorders are added away from the boundary region of TI 1210. Therefore, the disorders scatter phonons and electrons in the bulk state. As result, the contribution to the thermoelectric-transport from the bulk state is decreased. Because the disorders are away from the surface region, it has little effect to the contribution to thermoelectric-transport from the boundary state. The zT of TI 1210 is thereby increased.

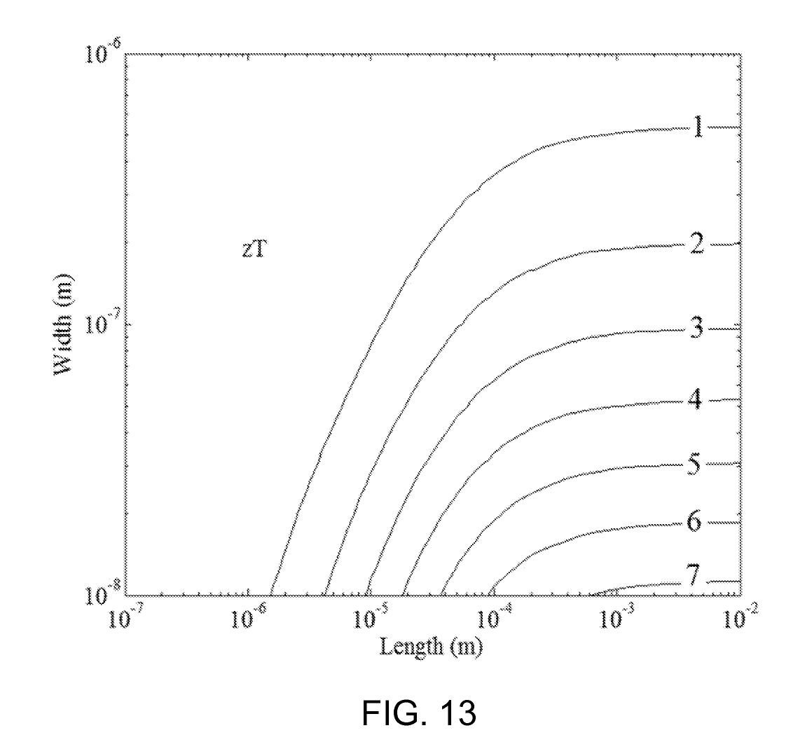

FIG. 13 is a diagram of the optimized zT as a function of length and width for a 2D TI fluorinated stanene at 300K. As shown in FIG. 13, the zT increases as the length of zT increases. It increases in the range of the mean free path length of the TI. It plateau at around 10⁻² m. The zT also increases as the width of the TI decreases. In one embodiment of the current invention, the optimized width of the TI is about three times of a localization width ξ of the boundary state of the TI. As shown in FIG. 13, zT of higher than three can be achieved in accordance to embodiments of the current invention.

In another preferred embodiment of the current invention, stanene is used a TI material to achieve high zT. Stanene is a monolayer tin film in a honeycomb lattice. Decorated Stanene can be used as a TI material to achieve high zT. Decorated Stanene, like fluorinated stanene is a stanene decorated by fluorine and has nontrivial bulk gap of 0.3 eV, suitable for room temperature operation. The flurotined stanene has a localization width about 4 nm. By tuning the width to about 10 nm, zT can be increased to seven as shown in FIG. 13. In other embodiments of the current invention, decorated Stanene can be decorated by one or more combinations of chemical groups of fluorine, chlorine, bromine, iodine and hydroxyl.

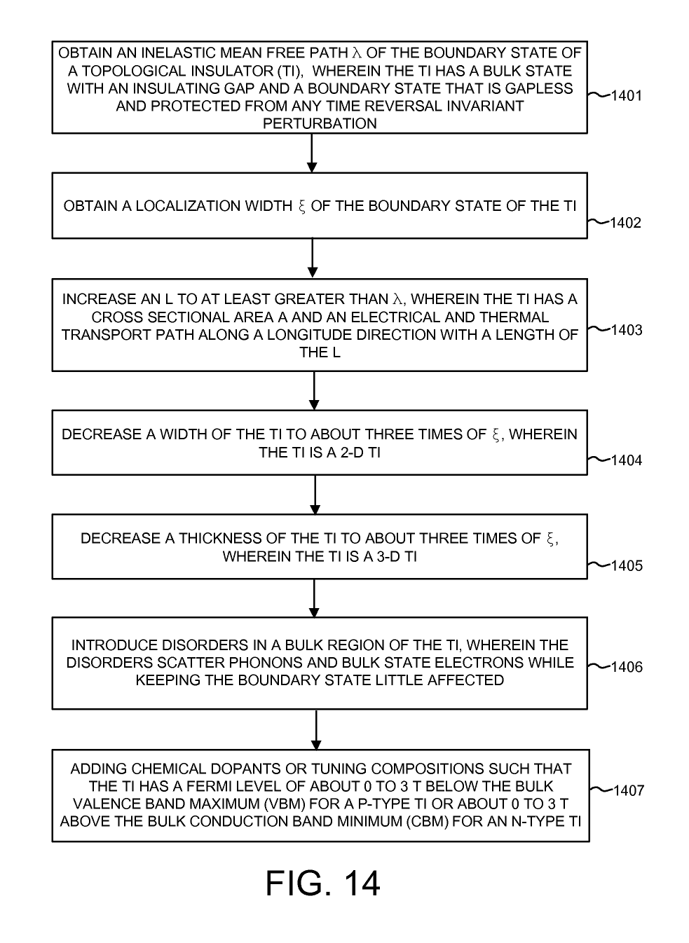

FIG. 14 is a flow diagram of methods to increase zT in according to embodiments of the current invention. Step 1401 obtains an inelastic mean free path λ of the boundary state of a topological insulator (TI), wherein the TI has a bulk state with an insulating gap and a boundary state that is gapless and protected from any time reversal invariant perturbation. Step 1402 obtains a localization width ξ of the boundary state of the TI. Step 1403 increases the length of the TI to at least greater than λ, wherein the TI has a cross sectional area A and an electrical and thermal transport path along a longitudinal direction with a length of the L. Step 1404 decreases a width of the TI to about three time of ξ, wherein the TI is a 2D TI. Step 1405 decreases a thickness of the TI to about three time of ξ, wherein the TI is a 3D TI. Step 1406 introduces disorders away from the boundary region of the TI, wherein the disorders scatter phonons and bulk state electrons while keeping the boundary state little affected. Step 1407 adds chemical dopants or tuning compositions such that the TI has a Fermi level of about zero to three k_{B}T below the bulk valence band maximum (VBM) for a P-Type TI or about zero to three k_{B}T above the bulk conduction band minimum (CBM) for an N-Type TI.

The disclosed methods to increase zT of the topological insulators apply to other topological materials, including quantum anomalous Hall insulators, such as thin films of chromium-doped (Bi,Sb)₂Te₃ and topological crystalline insulators (TCI), such as SnTe, Pb₁₋ₓSnₓTe, and Pb₁₋ₓSnₓSe. Quantum anomalous Hall insulators and topological crystalline insulators also have a bulk state with an insulating gap and a boundary state that is gapless and topologically protected. They can be used for thermoelectric applications in a way essentially the same as topological insulators. In quantum anomalous Hall insulators, where time reversal symmetry is broken, the boundary state is protected from any perturbation. In topological crystalline insulators, the boundary state is protected from any time reversal invariant perturbation if keeping crystalline symmetry. Similar to topological insulators, the zT for other topological materials is geometric size dependent. The zT of the topological materials can be optimized using the same methods applied to TIs as disclosed above.

Although the present invention has been described in connection with certain specific embodiments for instructional purposes, the present invention is not limited thereto. Accordingly, various modifications, adaptations, and combinations of various features of the described embodiments can be practiced without departing from the scope of the invention as set forth in the claims.

What is claimed is:

1. A thermoelectric structure comprising:
a topological insulator (TI), wherein the TI has a bulk state with an insulating gap and a boundary state that is gapless and protected from any time reversal invariant perturbation;
a cross sectional area A; and
an electrical and thermal transport path along a longitudinal direction with a length of L, wherein an electrical conductance G of the TI does not satisfy Ohm's scaling law that G is proportional to A/L, and wherein a thermoelectric figure of merit (ZT) of the thermoelectric structure is increased by increasing L and decreasing A.

2. The thermoelectric structure of claim 1, wherein the TI is a two-dimensional (2D) TI with topologically protected one dimensional edge state as the boundary state, and wherein a width of A is about three times of a localization width ξ of the boundary state of the TI.

3. The thermoelectric structure of claim 2, wherein the ZT is greater than 3.

4. The thermoelectric structure of claim 2, wherein the TI is selected from a group of heterostructures comprising: HgTe/CdTe, InAs/GaSb, thin films of Si, Ge, Sn, Sb, Bi, Bi2TeI, ZrTe5 and HfTe5, and wherein the width is about 10 to 100 nm.

5. The thermoelectric structure of claim 2, wherein the TI is a thin film alloy in which the alloying element is at least one of Bi2Te3, Sb2Te3 and Bi2Se3.

6. The thermoelectric structure of claim 1 further comprising:
chemical dopants such that the TI has a Fermi level of about 0 to 3 k_{B}T below the bulk valence band maximum (VBM) for a P-Type TI or about 0 to 3 k_{B}T above the bulk conduction band minimum (CBM) for an N-Type TI, wherein k_{B} is the Boltzman constant and T is an average temperature of the TI.

7. The thermoelectric structure of claim 1 wherein the TI is formed from material (BiₓSb₁₋ₓ)₂Te₃, wherein 0≦x≦1 such that the TI has a Fermi level of about 0 to 3 k_{B}T below the bulk valence band maximum (VBM) for a P-Type TI or about 0 to 3 k_{B}T above the bulk conduction band minimum (CBM) for an N-Type TI, wherein k_{B} is the Boltzman constant and T is an average temperature of the TI.

8. The thermoelectric structure of claim 7, wherein x is about 0 to 0.1 for a P-type TI, and wherein x is about 0.9 to 1 for an N-type TI.

9. The thermoelectric structure of claim 2, wherein the TI is a monolayer tin film in a honeycomb lattice decorated by chemical functional groups selected from a group consisting of: fluorine, chlorine, bromine, iodine and hydroxyl.

10. The thermoelectric structure of claim 10, wherein the width of the TI is about 10 nm.

11. The thermoelectric structure of claim 1 further comprising:
disorders away from a boundary region of the TI that scatter phonons and bulk state electrons while keeping the boundary state little affected.

12. The thermoelectric structure of claim 1, wherein the ZT is increased by increasing L to at least greater than an inelastic mean free path λ of the TI.

13. The thermoelectric structure of claim 1, wherein the TI is a three-dimensional (3D) TI with topologically protected two-dimensional surface state as the boundary state and a thickness of A is about three times of a localization width ξ of the boundary state of the TI.

14. A method comprising:
obtaining an inelastic mean free path λ of a topological insulator (TI), wherein the TI has a bulk state with an insulating gap and a boundary state that is gapless and protected from any time reversal invariant perturbation;
obtaining a localization width ξ of the boundary state of the TI; and
increasing a thermoelectric figure of merit (ZT) of the TI by substantially maximizing a relative thermoelectric-transport contribution of the boundary state with respect to the bulk states based on λ and ξ.

15. The method of claim 14, wherein the TI has a cross sectional area A and an electrical and thermal transport path along a longitudinal direction with a length of L, and wherein the increasing of the ZT involves increasing L to at least greater than λ.

16. The method of claim 14, wherein the TI is a two-dimensional (2D) with topologically protected one dimensional edge state as the boundary state, and the increasing of the ZT involves decreasing a width of the TI to about three times of ξ.

17. The method of claim 16, further comprising:
tuning a Fermi level of the TI to about 0 to 3 k_{B}T below the bulk valance band maximum (VBM) for a P-Type TI or about 0 to 3 k_{B}T above the bulk conduction band minimum (CBM) for an N-Type TI, wherein k_{B} is the Boltzman constant and T is an average temperature of the TI.

18. The method of claim 17, wherein the tuning of the Fermi level involves electrical gating.

19. The method of claim 17, wherein the tuning of the Fermi level involves adding chemical dopants.

20. The method of claim 14, further comprising:
introducing disorders away from a boundary region of the TI, wherein the disorders scatter phonons and bulk state electrons while keeping the boundary state little affected.

21. The method of claim 14, wherein the TI is a three-dimensional (3D) TI with topologically protected two-dimensional surface state as the boundary state, and wherein the increasing of ZT involves decreasing a thickness of the TI to about three times of ξ.
